(19) United States
(12) Patent Application Publication
(10) Pub. No.: US 2026/0291207 A1
(43) Pub. Date: Sep. 24, 2026

(54) ELECTRICAL CIRCUIT

(71) Applicant: Blixt Tech AB, Kista (SE)

(72) Inventors: Jan JOHANSSON, Solna (SE); Kasun HEWAGE, Uppsala (SE)

(73) Assignee: Blixt Tech AB, Kista (SE)

(21) Appl. No.: 19/480,062

(22) PCT Filed: May 5, 2024
(86) PCT No.: PCT/SE2024/050428

§ 371 Date: Oct. 30, 2025

(30) Foreign Application Priority Data
May 5, 2023 (SE) 2350552-2

(51) Int. Cl. H02H 3/20; H02H 3/02; H03K 17/30

(52) U.S. Cl. CPC H02H 3/20; H02H 3/021; H03K 17/302

(57) ABSTRACT

Embodiments of the invention relates to an electrical circuit comprising: an electrical power source; an electrical load connected between the electrical power source and a reference ground; and at least one transistor connected in parallel with the electrical load between the electrical power source and the reference ground, wherein the transistor comprises a diode arranged in a direction opposite to a current direction in the electrical circuit and a conductive channel, wherein the electrical circuit is configured to: deactivate the conductive channel of the transistor when an absolute value of a voltage difference between the electrical power source and the reference ground is larger than a first threshold value.

### TECHNICAL FIELD

Embodiments of invention relate to an electrical circuit.

### BACKGROUND

An electrical circuit may interconnect one or more electrical components to a power source and a reference ground in a closed loop so that a current may flow in the electrical circuit from the power source to the load. The electrical circuit may also be denoted an electrical network.

The power source usually provides a direct current or an alternating current to the load. The electrical components may be active components or passive components and may be connected in series or in parallel in relation to each other. The reference ground may be the same as the earth ground or a virtual ground.

### SUMMARY

An objective of embodiments of the invention is to provide a solution which mitigates or solves the drawbacks and problems of conventional solutions.

Another objective of embodiments of the invention is to provide a solution for camping back currents due to inductive loads.

The above and further objectives are solved by the subject matter of the independent claims. Further embodiments of the invention can be found in the dependent claims.

According to an aspect of the invention, the above mentioned and other objectives are achieved with an electrical circuit comprising:
an electrical power source;
an electrical load connected between the electrical power source and a reference ground; and
at least one transistor connected in parallel with the electrical load between the electrical power source and the reference ground, wherein the transistor comprises a diode arranged in a direction opposite to a current direction in the electrical circuit and a conductive channel, wherein the electrical circuit is configured to:
deactivate the conductive channel of the transistor when an absolute value of a voltage difference between the electrical power source and the reference ground is larger than a first threshold value.

The absolute value of the voltage difference may also be denoted the modules of the voltage difference. Thus, the electrical circuit is applicable for both current directions, i.e., from the electrical power source to the reference ground or from the reference ground to the electrical power source depending on the polarity of the electrical power source.

An advantage of the electrical circuit disclosed herein is that the electrical circuit prevents the generation of overvoltage(s) caused by inductive loads. This is especially the case for electrical components connected to the electrical circuit. Thus, an effective clamping circuit is provided.

In an embodiment of the invention, the electrical circuit is configured to:
activate the conductive channel of the transistor when the absolute value is larger than a second threshold value.

In an embodiment of the invention, the first threshold value is larger than 0.00 V, or larger than 0.10 V, or larger than 0.25 V, or larger than 0.50 V.

In an embodiment of the invention, the second threshold value is smaller than the first threshold value.

In an embodiment of the invention, the electrical load is an inductive load.

In an embodiment of the invention, the electrical circuit is configured to:
deactivate the conductive channel of the transistor when the absolute value is larger than the first threshold value thereby clamping a back electromotive force current in the circuit.

In an embodiment of the invention, the electrical circuit comprises a first control device connected between the electrical power source and the transistor and configured to activate and deactivate the conductive channel of the transistor.

In an embodiment of the invention, the first control device comprises a resistance connected between the electrical power source and a control pin of the transistor.

In an embodiment of the invention, the first control device further comprises a driver connected in series with the resistance.

In an embodiment of the invention, the driver is connected to a control pin of the transistor.

In an embodiment of the invention, the electrical circuit comprises a second control device connected between the electrical power source and the transistor and being configured to activate and deactivate the conductive channel of the transistor.

In an embodiment of the invention, the second control device comprises a voltage measurement circuit, a threshold circuit, and a driver circuit interconnected with each other.

In an embodiment of the invention,
the voltage measurement circuit is configured to measure the voltage difference between the electrical power source and the reference ground;
the threshold circuit is configured to output a control signal to the driver circuit; and
the driver circuit is configured to activate/deactivate the conductive channel of the transistor in response to the reception of the control signal from the threshold circuit.

In an embodiment of the invention, the electrical circuit comprises a first transistor and a second transistor connected in series with each other in opposite current directions.

In an embodiment of the invention, the conductive channel of the first transistor and the conductive channel of the second transistor are configured to not being conductive at the same time instance.

In an embodiment of the invention, the electrical circuit comprises an electrical component connected between the electrical power source and the transistor and the electrical load.

In an embodiment of the invention, the electrical component is an electrical switch.

In an embodiment of the invention, the electrical switch is configured to switch to its non-conductive state when the conductive channel of the transistor has been activated.

In an embodiment of the invention, the electrical circuit comprises a current delay circuit connected between the electrical power source and the transistor and the electrical load.

In an embodiment of the invention, the current delay circuit is connected in series with the electrical component between the electrical power source and the transistor and the electrical load.

In an embodiment of the invention, the electrical load is configured to be switched between an ON-state in which the electrical load consumes electrical power and an OFF-state in which the electrical load does not consume electrical power.

In an embodiment of the invention, the electrical load is configured to switch between a galvanic state in which the electrical load is in galvanic contact with other components of the electrical circuit and a non-galvanic state in which the electrical load is in non-galvanic contact with any other components of the electrical circuit.

In an embodiment of the invention, the reference ground is an earth ground or a virtual ground.

Further applications and advantages of embodiments of the invention will be apparent from the following detailed description.

### BRIEF DESCRIPTION OF THE DRAWINGS

The appended drawings are intended to clarify and explain different embodiments of the invention, in which:

FIGS. 1 and 2 show an electrical circuit according to embodiments of the invention;

FIG. 3 shows two transistors connected in opposite directions;

FIG. 4 shows an electrical circuit comprising an electrical component according to embodiments of the invention;

FIG. 5 shows an electrical circuit comprising a control line according to embodiments of the invention;

FIGS. 6 and 7 show an electrical circuit for electrical safety according to embodiments of the invention; and

FIGS. 8 and 9 show an electrical circuit for electrical safety according to further embodiments of the invention.

### DETAILED DESCRIPTION

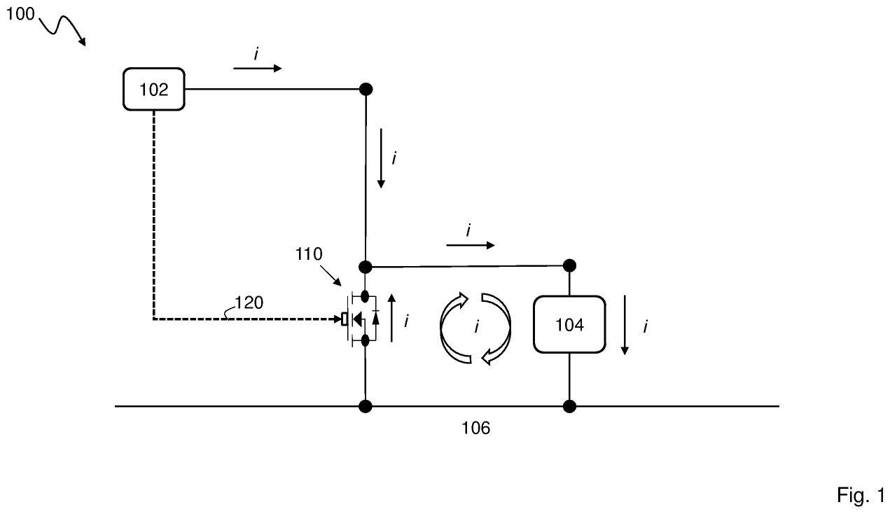

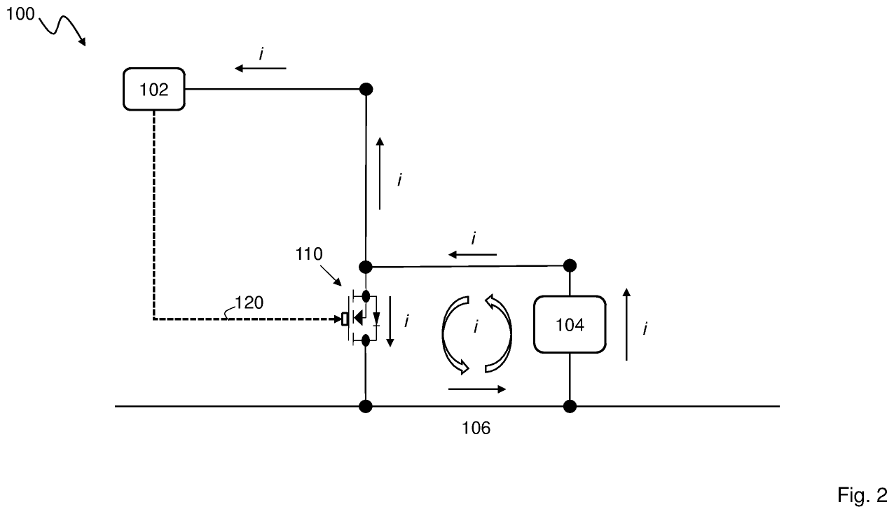

FIGS. 1 and 2 show an electrical circuit 100 according to embodiments of the invention where FIG. 1 illustrates the case when the electrical power source 102 is a positive direct current (DC) source while FIG. 2 illustrates the case when the electrical power source 102 is a negative DC source. According to embodiments of the invention the electrical circuit 100 comprises an electrical power source 102 which is configured to provide an electrical current i to an electrical load. The electrical power source 102 may thus be configured to provide a positive DC, a negative DC, an alternating current (AC) with a single phase and an AC with multiple phases such as three-phase AC. The voltage of the electrical power source 102 may in embodiments of the invention be the rated voltage for USA or Europe. Thus, the electrical power source 102 is configured to provide AC or DC having mean value of 110 V or 220-230 V.

The electrical circuit 100 further comprises an electrical load 104 connected between the electrical power source 102 and the reference ground 106. The latter may be an actual earth ground having the same potential as the earth. However, the reference ground 106 may in other cases be a virtual ground for the components of the electrical circuit 100 which is different to the earth ground. In yet other examples, the transistor 110 may be connected to a first reference ground while the electrical load 104 connected to a second reference ground where the first reference ground and the second reference ground have different voltage potentials.

The electrical load 104 may be any type of electrical load which generally consumes electrical power for its functioning. In examples, the electrical load 104 is configured to be switched between an ON-state in which the electrical load 104 consumes electrical power and an OFF-state in which the electrical load 104 does not consume electrical power. Such types of electrical loads will generally generate electric arcs when they are switched between the ON-state and the OFF-state which is handled by the present electrical circuit 100. The electrical load 104 may be an inductive load such as an electrical motor in embodiments of the invention.

In addition to the ON and OFF property mentioned above, the electrical load 104 may also be configured to be switched between a galvanic state in which the electrical load 104 is in galvanic contact with other components of the electrical circuit 100 and a non-galvanic state in which the electrical load 104 is in non-galvanic contact with any other components of the electrical circuit 100. In the non-galvanic state, the electrical load 104 is so-called galvanic isolated from the rest of the electrical circuit 100. The switching into galvanic and non-galvanic state may be controlled by a control device.

The electrical circuit 100 further comprises at least one transistor 110 connected in parallel with the electrical load 104 between the electrical power source 102 and the reference ground 106 as shown in the appended Figs. The transistor 110 comprises a diode 112 arranged in a direction opposite to a current direction/in the electrical circuit 100 as shown in FIG. 1 for the positive DC case (i.e., positive polarity) and in FIG. 2 for the negative DC case (i.e., negative polarity).

The transistor 110 also comprises a conductive channel configured to be deactivated when an absolute value of a voltage difference between the electrical power source 102 and the reference ground 106 is larger than a first threshold value. Since the absolute value or the modulus of the voltage difference is considered both possible current directions in the electrical circuit 100 may be handled. Thus, the electrical circuit 100 is configured to deactivate the conductive channel of the transistor 110 when an absolute value of a voltage difference between the electrical power source 102 and the reference ground 106 is larger than the first threshold value. More particularly, the electrical circuit 100 may be configured to deactivate the conductive channel of the transistor 110 when the absolute value is larger than the first threshold value thereby clamping a back electromotive force current generated in the circuit. This is applicable when the load 104 is an inductive load.

That the conductive channel of the transistor 110 is deactivated may be understood that a current cannot pass through the conductive channel contrary to when the conductive channel is activated and a current can flow in the conductive channel. Thus, when the conductive channel is deactivated, the current can only pass the transistor 110 through the diode 112 and hence only in the direction of the diode 112. The above reasoning also implies that the conductive channel of the transistor 110 is configured to be activated and deactivated, i.e., being switched between conductive and non-conductive states.

Therefore, in embodiments of the invention, the electrical circuit 100 is configured to activate the conductive channel of the transistor 110 when the absolute value is larger than a second threshold value. There is a relationship between the first threshold value and the second threshold value which may be stated such that the second threshold value is smaller than the first threshold value in embodiments of the invention.

In further embodiments of the invention, the first threshold value for deactivating the conductive channel is larger than 0 V meaning that when there is a difference in potential between the electrical power source 102 and the reference ground 106, the conductive channel is deactivated so that the current in the electrical circuit 100 only can pass through the diode 112 in the diode direction of the transistor 110. This has the implication that when the conductive channel is deactivated, the current i will circulate between the transistor 110 and the load 104 in the direction of the diode 112 when the current fed to the electrical load 104 disappears e.g., when an electrical/mechanical component breaks the circuit 100, when the load 104 is switched from the ON-state to the OFF-state, or when the electrical load 104 is switched from galvanic contact to galvanic isolation. In FIG. 1 the direction of current circulation is clockwise since the power source 102 provides a positive DC. The opposite direction, i.e., the anticlockwise direction, is the case shown in FIG. 2 since the power source 102 here provides a negative DC. In embodiments of the invention, the first threshold value is larger than 0.10 V, or larger than 0.25 V, or larger than 0.50 V.

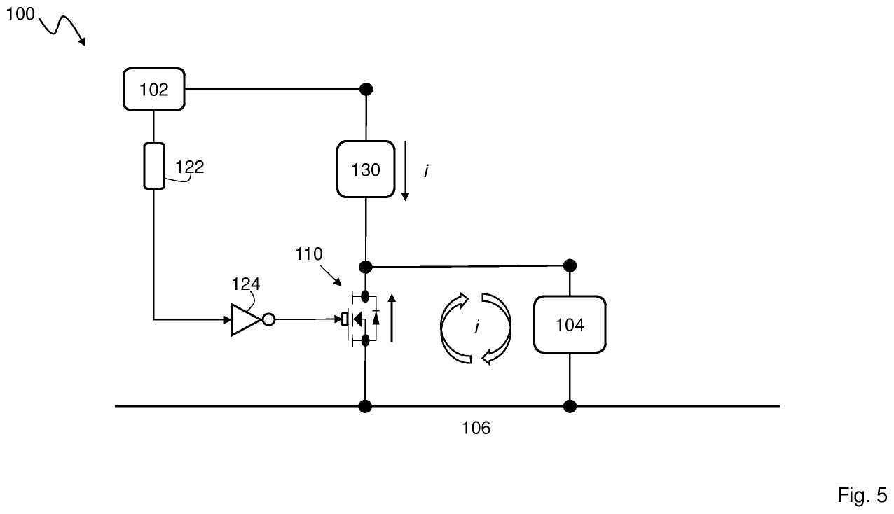

It is further noted that FIGS. 1 and 2 show a first control device connected between the electrical power source 102 and the transistor 110 for controlling the transistor 110 and more specifically the conductive channel of the transistor 110. The first control device may comprise a control line 120 suitable for controlling the transistor 110 and an embodiment of the control line 120 is described below with reference to FIG. 5.

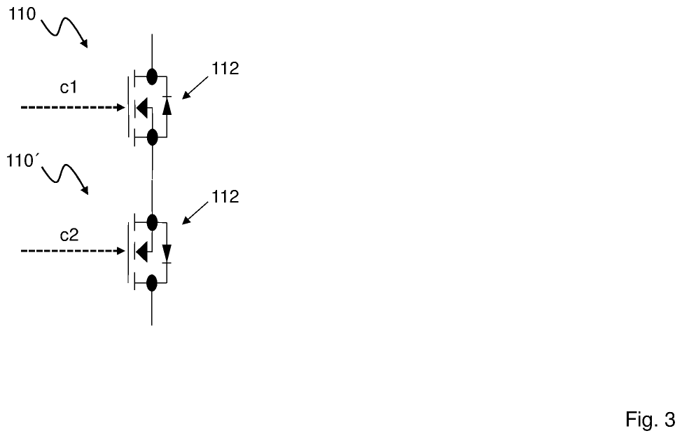

Furthermore, when the power source 102 is configured to provide a single-phase AC or multiphase AC to the load 104 a set-up of two transistors is needed to handle both current directions of the AC. FIG. 3 shows such an example when two transistors are connected in opposite directions. As shown in FIG. 3, the electrical circuit 100 comprises a first transistor 110 and a second transistor 110′ connected in series with each other in opposite current directions. This means that the diodes 112, 112′ of the first 110 and second 100′ transistors are arranged in opposite directions thus blocking current in opposite directions. By replacing the single transistor 110 in FIGS. 1 and 2 with the two-transistor arrangement shown in FIG. 3, AC applications can be handled by embodiments of the present invention as well as applications where the direction of the current switches between positive DC and negative DC without being an AC. The conductive channel of the first transistor 110 and the conductive channel of the second transistor 110′ are configured to not being conductive at the same time instance in embodiments of the invention.

The transistor(s) herein used may be any suitable type of transistor comprising a conductive channel and a diode such as N-MOS or P-MOS. The transistor 110 may have a gate G, a drain D, and a source S. The drain D of the transistor 110 may connected to the power source 102, the source S of the transistor 110 may be connected to the reference ground 106 and the gate G of the transistor 110, which is used to control the transistor, may be connected to a control line 120 connecting the gate G of the transistor to the power source 102 via the control line 120.

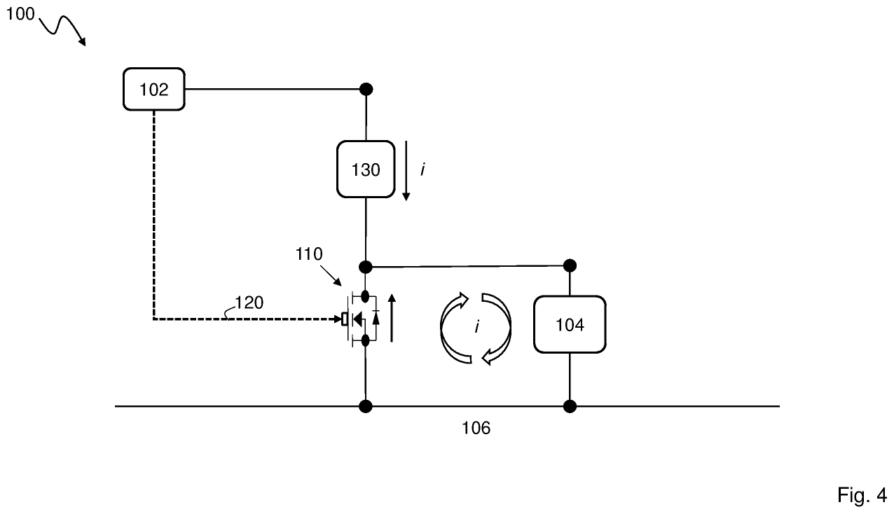

FIG. 4 shows the electrical circuit 100 comprising an electrical component 130 according to embodiments of the invention. The electrical component 130 may be any type of electrical component such as resistors, switches, varistors, fuses, inductors, and transformers. It is noted that the electrical component 130 is connected between the electrical power source 102 and the transistor 110 and the electrical load 104. The electrical component 130 will be protected from overvoltage/overcurrent thanks to the herein disclosed invention.

It was previously mentioned that the electrical circuit 100 may also comprise a first control device for controlling the transistor 110. FIG. 5 therefore shows more in detail a first control device for the electrical circuit 100 according to embodiments of the invention. As shown in FIG. 5, the first control device comprises a control line 120 that is connected between the electrical power source 102 and the transistor 110 for activating/deactivating the conductive channel of the transistor 110. That the control line 120 is connected to the electrical power source 102 may be understood that the control line 120 is directly connected to the electrical power source 102 or indirectly via a monitoring circuit/interface for obtaining the potential value of the electrical power source 102 to be compared to the potential value of the reference ground 106.

The first control device can in examples of the invention comprise a resistance 122 and a driver circuit 124 which are connected in series with each other between the electrical power source 102 and the transistor 110 as shown in FIG. 5. More specifically, the driver 124 or the resistance 122 may be connected to a control pin of the transistor 110 for controlling the same. The driver 124 may be non-inverted driver or an inverted driver depending in the type of transistor 110 and the polarity of the current. It should be noted that the control line 120 may in examples of the invention only comprise the resistance 122 without the driver 124. In that case the polarity of the control signal may have to be inverted which can be made with an inverter circuit. The configuration with a resistance 122 but without a driver 124 however implies that the time for deactivating the conductive channel will be longer compared to the configuration with a driver 124.

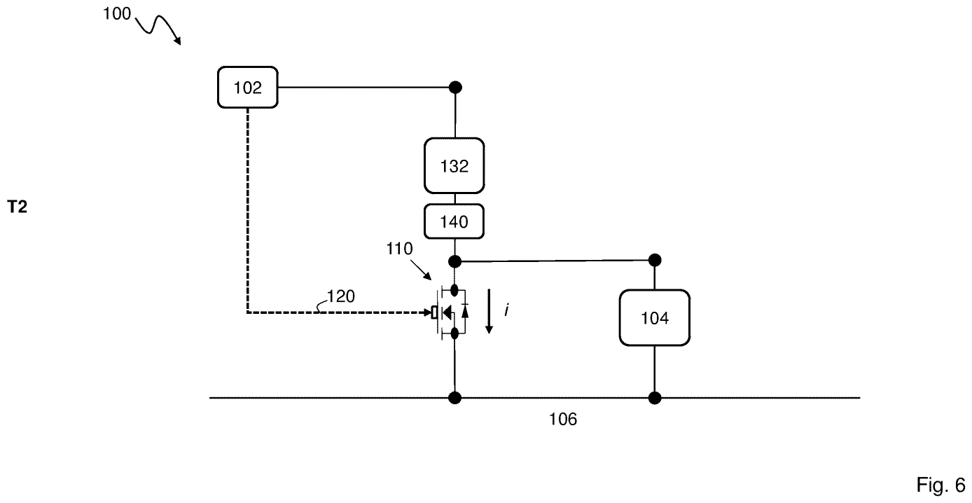

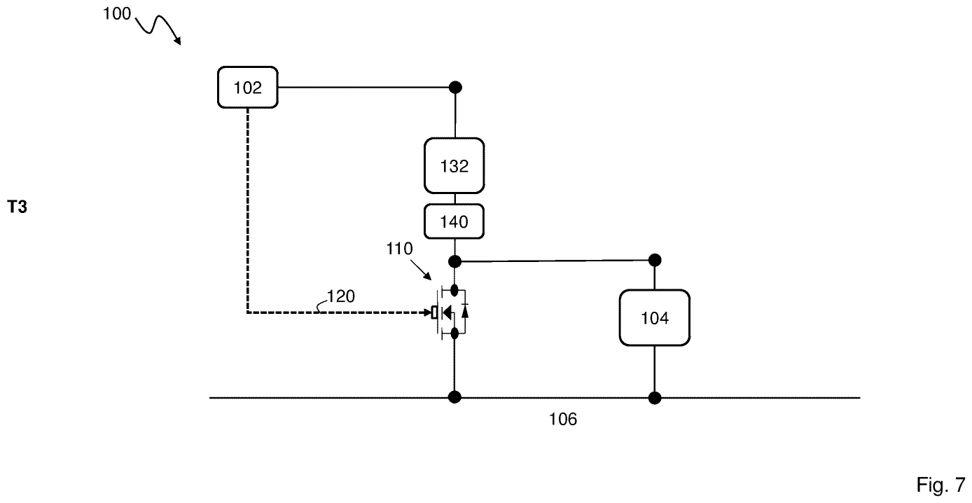

Moreover, FIGS. 6 and 7 show an electrical circuit 100 for providing electrical safety thereby protecting a person from electrical harm when being in contact with the electrical circuit 100 according to embodiments of the invention. In this respect, the electrical component 130 is an electrical switch 132 which may be controlled by a control arrangement or device (not shown in the Figs). The electrical switch 132 is configured to switch from is conductive state to its non-conductive state when the conductive channel of the transistor 110 is activated which now will be explained with reference to FIGS. 6 and 7. However, it may be noted that the activation/deactivation may be autonomous from the control of the electrical switch 132, i.e., the electrical switch 132 may be controlled independently of the activation/deactivation of the conductive channels of the transistors.

At a first time instance T1 (not shown in the FIG. 6 or 7), the electrical switch 132 is in its conductive state and a current is fed to the electrical load 104 since the conductive channel of the transistor 110 is set in its non-active state and is therefore not conductive.

At a second time instance T2, shown in FIG. 6, following the first time instance T1, the transistor 110 is set to be conductive, i.e., the conductive channel has been activated, which means a short circuit and the current i will flow via the transistor 110 to the reference ground instead of via the electrical load 104.

At a third time instance T3, shown in FIG. 7, following the second time instance T2, the electrical switch 132 is switched to its non-conductive state thus blocking the current from flowing in the circuit 100.

For improved electrical safety, the electrical circuit 100 may also comprise a current delay circuit 140, also denoted current limiting circuit, being connected between the electrical power source 102 and the transistor 110 and the electrical load 104. The current delay circuit 140 is connected in series with the electrical component 130 between the electrical power source 102 and the transistor 110 and the electrical load 104. The current delay circuit 130 will delay the increase of the current in the electrical circuit 100 so that the electrical switch 132 can be switched during the third time period T3 to its non-conductive state thereby blocking current from the power source 102.

In embodiments of the invention, the current delay circuit 140 is configured to directly or indirectly switch the electrical switch 132 from its conductive state into its non-conductive state when a current at the current delay circuit 140 is larger than the threshold current Th_{c}. The threshold current The can however be translated to a corresponding threshold voltage Thᵥ. In such case, a corresponding voltage at the current delay circuit 140 may be monitored and the electrical switch 132 will be set or switched into its non-conductive state if the monitored voltage exceeds a threshold voltage Thᵥ corresponding to the current threshold Th_{c}. The voltage in the electrical circuit 100 increases before the current increase which means that suitable actions can be taken before the current reaches dangerous levels, i.e., to switch off the electrical switch 132.

Solid state switchgear (SSSG) devices/components such as solid-state relays or solid-state circuit breakers offer several advantages in electrical power distribution systems compared to their mechanical counterparts, thanks to their increased speed and arc-free operation. One common type of loads used with electrical power distribution systems is inductive loads as aforementioned. Back electromotive force (EMF) is a phenomenon that causes a voltage spike across the inductive load when the electrical current through the inductive load is suddenly changed or interrupted. The generated voltage spike could easily exceed the rated operating voltage of the electronic components used in SSSG devices, resulting in damage and destruction. Some of the conventional used solutions to clamp the back EMF current include using transient voltage suppressor (TVS) diodes or metal oxide varistors (MOVs), and voltage snubber circuits. SSSGs often handle high currents and voltages, necessitating high power ratings for TVSs, MOVs, and snubber circuits. However, high-power components are often expensive, hence increasing the overall cost of such solutions. Embodiments of the invention are designed to solve the aforementioned drawbacks of conventional solutions by providing a clamping circuit for use in both AC and DC applications. A high-level concept of the proposed clamping circuit is to provide a different current path for the generated back EMF voltage.

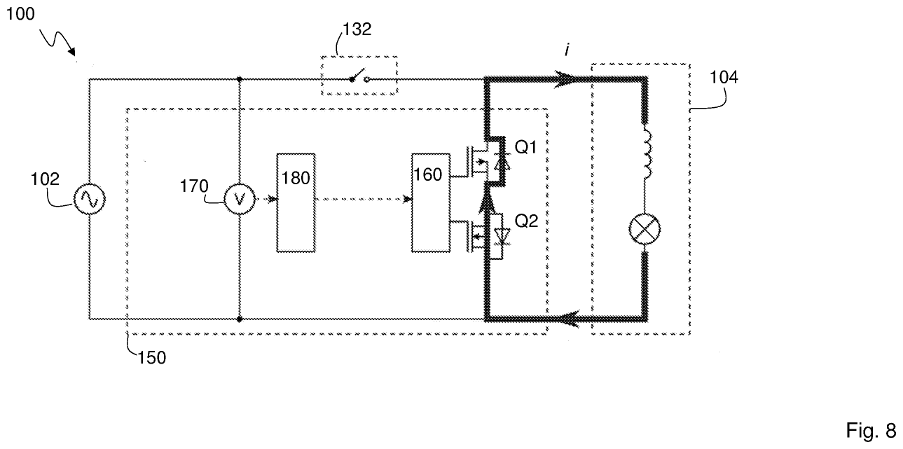

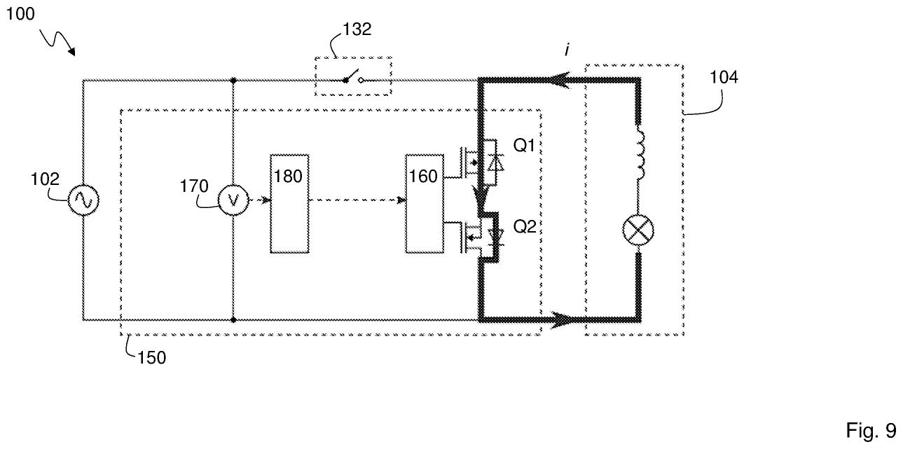

FIGS. 8 and 9 thus show abstract schematic of an electrical circuit 100 comprising a clamping circuit 150 according to further embodiments of the invention. In the shown embodiment in FIGS. 8 and 9, the clamping circuit 150 comprises two transistors 110, 110′ herein also denoted Q1 and Q2, respectively, which are connected in parallel to an inductive load 104. The transistors Q1 and Q2 are connected in series with each other in opposite current directions. The two transistors Q1 and Q2 have built-in body diodes or externally connected diodes, as depicted in the Figs. Moreover, a SSSG is connected between the voltage source 102 and the inductive load 104. Thus, the SSSG is acting as an electrical switch 132 in these cases, but other electrical switches may be used.

The clamping circuit 150 also comprises a second control device which includes a driver circuit 160 which is configured to supply a necessary voltage/current to switch the two transistors Q1 and Q2 between an ON state and an OFF state. A voltage measurement circuit 170 of the second control device is configured to measure the voltage at the input of the SSSG and further configured to feed the measured voltage readings to a threshold circuit 180 of the second control device. The threshold circuit 180 is configured to output a control signal to the driver circuit 160 which is configured to independently switch transistors Q1 and Q2 between the ON state and the OFF state depending on the value of the voltage at the input of the SSSG and voltage threshold values. The voltage threshold values may be adapted to different applications and thus comprise different threshold values depending on the application. The ON state of the transistor corresponds to when the conductive channel of the transistor is activated and the OFF state of the transistor corresponds to when the conductive channel of the transistor is deactivated. Thus, a current can flow in the conductive channel when the transistor is in its ON state and a current cannot flow in the conductive channel when the transistor is in its OFF state.

The transistors Q1 and Q2 may be different operational states S1, S2 and S3 represent the combined states of transistors Q1 and Q2. When in state S1 Q1 is OFF and Q2 is ON, when in state S2 Q1 is OFF and Q2 is OFF, and when in state S3 Q1 is ON and Q2 is OFF. It may be noted that the two transistors should never be conductive at the same time instance as previously mentioned.

Thresholds V_{n_th_l}, V_{n_th_h}, V_{p_th_l} and V_{p_th_h}, where n=negative, p=positive, h=high, l=low, for controlling the transistors Q1, Q2 may be empirically determined values depending on the application. It may be noted that the second state S2 is an initial state when the output of the voltage source 102 is 0 V. When the voltage source 102 is a DC source the polarity may be positive or negative. If positive polarity the first state S1 represents the state of the transistors. If negative polarity the third state S3 represents the state of the transistors. For example, the first state S1 is applicable if 0<V_{p_th_h}<Vᵢₙ and the third state S3 is applicable if 0>V_{n_th_h}>Vᵢₙ.

FIG. 8 depicts the current flow in the circuit with bold lines and arrows generated from the back EMF current when the transistors Q1 and Q2 are in the first state S1. The current flows through the built-in body diode (or the externally added diode) of transistor Q1 because transistor Q1 is in the OFF state. Correspondingly, transistor Q2's built-in body diode conducts the current when the transistors Q1 and Q2 are in the third state S3 as shown in FIG. 9.

Thus, it is herein disclosed proactive clamping of the back EMF current by turning ON and OFF transistors Q1 and Q2 based on the measured voltage at the input of the electrical switch 132, in this case the SSSG. The proactive clamping is due to the fact that the measured voltage at the input of the SSSG is used for clamping by controlling the transistors Q1 and Q2.

Hence, according to embodiments of the invention, the maximum clamped voltage would be the forward voltage of the body diode (or external diode) of transistors Q1 and Q2, which is typically less than 1 V. Furthermore, this approach differs from solutions involving TVSs or MOVs, where the back EMF current is reactively clamped at a much higher voltage level.

Finally, it should be understood that the invention is not limited to the embodiments described above, but also relates to and incorporates all embodiments within the scope of the appended independent claims.

1. An electrical circuit comprising:
an electrical power source;
an electrical load connected between the electrical power source and a reference ground; and
at least one transistor connected in parallel with the electrical load between the electrical power source and the reference ground, wherein the transistor comprises a diode arranged in a direction opposite to a current direction in the electrical circuit and a conductive channel, wherein the electrical circuit is configured to:
deactivate the conductive channel of the transistor when an absolute value of a voltage difference between the electrical power source and the reference ground is larger than a first threshold value.

2. The electrical circuit according to claim 1, wherein the electrical circuit is configured to:
activate the conductive channel of the transistor when the absolute value is larger than a second threshold value.

3. The electrical circuit according to claim 1, wherein the first threshold value is larger than 0.00 V, or larger than 0.10 V, or larger than 0.25 V, or larger than 0.50 V.

4. The electrical circuit according to claim 1, wherein the second threshold value is smaller than the first threshold value.

5. The electrical circuit according to claim 1, wherein the electrical load is an inductive load.

6. The electrical circuit according to claim 1, wherein the electrical circuit is configured to:
deactivate the conductive channel of the transistor when the absolute value is larger than the first threshold value thereby clamping a back electromotive force current in the circuit.

7. The electrical circuit according to claim 1, comprising a first control device connected between the electrical power source and the transistor and configured to activate/deactivate the conductive channel of the transistor.

8. The electrical circuit according to claim 7, wherein the first control device comprises a resistance connected between the electrical power source and a control pin of the transistor.

9. The electrical circuit according to claim 8, wherein the first control device further comprises a driver connected in series with the resistance.

10. The electrical circuit according to claim 9, wherein the driver is connected to a control pin of the transistor.

11. The electrical circuit according to claim 1, comprising a second control device connected between the electrical power source and the transistor and configured to activate/deactivate the conductive channel of the transistor.

12. The electrical circuit according to claim 11, wherein the second control device comprises a voltage measurement circuit, a threshold circuit, and a driver circuit interconnected with each other.

13. The electrical circuit according to claim 12, wherein
the voltage measurement circuit is configured to measure the voltage difference between the electrical power source and the reference ground;
the threshold circuit is configured to output a control signal to the driver circuit; and
the driver circuit is configured to activate/deactivate the conductive channel of the transistor in response to the reception of the control signal from the threshold circuit.

14. The electrical circuit according to claim 1, comprising a first transistor and a second transistor connected in series with each other in opposite current directions.

15. The electrical circuit according claim 14, wherein the conductive channel of the first transistor and the conductive channel of the second transistor are configured to not being conductive at the same time instance.

16. The electrical circuit according to claim 1, comprising an electrical component connected between the electrical power source and the transistor and the electrical load.

17. The electrical circuit according to claim 16, wherein the electrical component is an electrical switch.

18. The electrical circuit according to claim 17, wherein the electrical switch is configured to switch to its non-conductive state when the conductive channel of the transistor has been activated.

19. The electrical circuit according to claim 16, comprising a current delay circuit connected between the electrical power source and the transistor and the electrical load.

20. The electrical circuit according to claim 19, wherein the current delay circuit is connected in series with the electrical component between the electrical power source and the transistor and the electrical load.

21. The electrical circuit according to claim 1, wherein the electrical load is configured to be switched between an ON-state in which the electrical load consumes electrical power and an OFF-state in which the electrical load does not consume electrical power.

22. The electrical circuit according to claim 1, wherein the electrical load is configured to switch between a galvanic state in which the electrical load is in galvanic contact with other components of the electrical circuit and a non-galvanic state in which the electrical load is in non-galvanic contact with any other components of the electrical circuit.

23. The electrical circuit according to claim 1, wherein the reference ground is an earth ground or a virtual ground.
